(19) United States
(12) Patent Application Publication
(10) Pub. No.: US 2022/0187495 A1
(43) Pub. Date: Jun. 16, 2022

(54) SYSTEM AND METHOD FOR APPLYING ARTIFICIAL INTELLIGENCE TECHNIQUES TO RESERVOIR FLUID GEODYNAMICS

(71) Applicant: Schlumberger Technology Corporation, Sugar Land, TX (US)

(72) Inventors: Denise E. Freed, Highlands, MA (US); Harish Baban Datir, Tananger (NO); Peter Tilke, Watertown, MA (US); Oliver C. Mullins, Houston, TX (US); Lalitha Venkataramanan, Lexington, MA (US); Sandip Bose, Brookline, MA (US)

(21) Appl. No.: 17/310,991

(22) PCT Filed: Mar. 11, 2020
(86) PCT No.: PCT/US2020/022003

§ 371 Date: Sep. 3, 2021

Related U.S. Application Data
(60) Provisional application No. 62/816,654, filed on Mar. 11, 2019.

(51) Int. Cl. G01V 99/00; G06F 30/28; G06F 30/27; E21B 49/08

(52) U.S. Cl. CPC G01V 99/005; G06F 30/28; E21B 2200/20; E21B 49/0875; G06F 30/27

(57) ABSTRACT

Embodiments herein include a system and method for modeling and interpreting an evolution of fluids in an oilfield using artificial intelligence. Embodiments may include identifying, using at least one processor, one or more reservoir fluid dynamics processes or properties and generating a model for the one or more reservoir fluid dynamics processes or properties. Embodiments may include receiving, at the model, one or more parameter values corresponding to the one or more reservoir fluid dynamics processes or properties and displaying, at a graphical user interface, one or more results, based upon, at least in part, the model and the one or more parameter values.

### RELATED APPLICATIONS

This application claims the benefit of U.S. Provisional Application No. 62/816,654, filed on Mar. 11, 2019, the contents of which is incorporated herein by reference.

### FIELD OF THE INVENTION

The present disclosure relates to modeling and interpreting fluid complexities in an oilfield.

### BACKGROUND

Oilfield operations (such as surveying, drilling, wireline testing, completions, production, and planning and oilfield analysis) are typically performed to locate and gather valuable downhole hydrocarbon fluids (such as oil and natural gas). The acquisition and interpretation of Downhole Fluid Analyses (“DFA”) alongside laboratory measurements of fluid samples acquired downhole (e.g., gas chromatography) are now a routine component of the well appraisal workflow. Many interacting phenomena over significant spans of geologic time (i.e., millions of years) affect the fluid composition observed at the present time. Thus, the interpretation of DFA and lab analyses are generally non-unique and dependent on expert knowledge, experience and creativity. In some cases, causal and probabilistic graphical models are applied to the upstream oil and gas industry.

### SUMMARY

This summary is provided to introduce a selection of concepts that are further described below in the detailed description. This summary is not intended to identify essential features of the claimed subject matter, nor is it intended to be used as an aid in limiting the scope of the claimed subject matter.

In an embodiment of the present disclosure, a method for modeling and interpreting an evolution of fluids in an oilfield using artificial intelligence is provided. The method may include identifying, using at least one processor, one or more reservoir fluid dynamics processes or properties and generating a model for the one or more reservoir fluid dynamics processes or properties. Embodiments may include receiving, at the model, one or more parameter values corresponding to the one or more reservoir fluid dynamics processes or properties and displaying, at a graphical user interface, one or more results, based upon, at least in part, the model and the one or more parameter values.

One or more of the following features may be included. In some embodiments, the model may be selected from a group consisting of: a probabilistic Bayesian network, a causal map and a factor graph. The model may include one or more possible interactions over a space and time and includes one or more uncertainties with a value of information. The model may relate the one or more reservoir fluid dynamics processes or properties to one or more effects on the fluids in one or more reservoirs and the one or more reservoir fluid dynamics processes or properties. The method may further include determining one or more ranges of values for the one or more parameter values. In some embodiments, determining may be performed by training, using the at least one processor, the model based upon, at least in part, known values of reservoir fluid dynamics processes or properties. The method may include determining one or more rules for at least one factor node associated with the factor graph. The method may further include applying one or more inference propagation algorithms to determine whether a particular process has occurred or has not occurred. The method may also include applying one or more inference propagation algorithms to identify a new reservoir fluid dynamics process or property. The method may also include providing the new reservoir fluid dynamics process or property to the model.

In another embodiment of the present disclosure, a system for modeling and interpreting an evolution of fluids in an oilfield using artificial intelligence is provided. The system may include a memory storing one or more reservoir fluid dynamics processes or properties. The system may also include a processor configured to identify one or more reservoir fluid dynamics processes or properties and to generate a model for the one or more reservoir fluid dynamics processes or properties. The processor may be further configured to receive, at the model, one or more parameter values corresponding to the one or more reservoir fluid dynamics processes or properties. The system may also include a graphical user interface configured to display one or more results, based upon, at least in part, the model and the one or more parameter values.

One or more of the following features may be included. In some embodiments, the model may be selected from a group consisting of: a probabilistic Bayesian network, a causal map and a factor graph. The model may include one or more possible interactions over a space and time and includes one or more uncertainties with a value of information. The model may relate the one or more reservoir fluid dynamics processes or properties to one or more effects on the fluids in one or more reservoirs and the one or more reservoir fluid dynamics processes or properties. The system may further include determining one or more ranges of values for the one or more parameter values. In some embodiments, determining may be performed by training, using the at least one processor, the model based upon, at least in part, known values of reservoir fluid dynamics processes or properties. The system may include determining one or more rules for at least one factor node associated with the factor graph. The system may further include applying one or more inference propagation algorithms to determine whether a particular process has occurred or has not occurred. The system may also include applying one or more inference propagation algorithms to identify a new reservoir fluid dynamics process or property. The system may also include providing the new reservoir fluid dynamics process or property to the model.

### BRIEF DESCRIPTION OF THE DRAWINGS

The subject disclosure is further described in the detailed description which follows, in reference to the noted plurality of drawings by way of non-limiting examples of the subject disclosure, in which like reference numerals represent similar parts throughout the several views of the drawings, and wherein:

FIG. 1 depicts a system diagram consistent with embodiments of the reservoir analysis process described herein;

FIG. 2 depicts a flowchart consistent with embodiments of the reservoir analysis process described herein;

FIG. 3 depicts a causal diagram representing biodegradation, subsidence, and spill-fill processes consistent with embodiments of the reservoir analysis process described herein;

FIG. 4 depicts a factor graph representation of the biodegradation process consistent with embodiments of the reservoir analysis process described herein; and

FIGS. 5-7 depict examples of graphical user interfaces consistent with embodiments of the reservoir analysis process described herein.

### DETAILED DESCRIPTION

Embodiments included herein are directed towards a framework to explain the observed and inferred fluid compositions, properties and distributions in a subsurface petroleum system. The current petroleum system has evolved over geologic time (i.e., millions of years) and was affected by sediment deposition, structural/tectonic effects, source rock evolution, migration, entrapment and biodegradation amongst other phenomena. Expert knowledge, experience and creativity are currently required to understand the integrated influences of these phenomena and infer other properties of the petroleum system. Embodiments included herein present an artificial intelligence framework for capturing this knowledge and applying it to semi-automatically interpret the possible evolution of the observed fluids. This will allow better decisions to be made with regard to measurement acquisition and field exploration and development.

The discussion below is directed to certain implementations and/or embodiments. It is to be understood that the discussion below may be used for the purpose of enabling a person with ordinary skill in the art to make and use any subject matter defined now or later by the patent “claims” found in any issued patent herein.

It is specifically intended that the claimed combinations of features not be limited to the implementations and illustrations contained herein, but include modified forms of those implementations including portions of the implementations and combinations of elements of different implementations as come within the scope of the following claims. It should be appreciated that in the development of any such actual implementation, as in any engineering or design project, numerous implementation-specific decisions may be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the claimed invention unless explicitly indicated as being “critical” or “essential.”

It will also be understood that, although the terms first, second, etc. may be used herein to describe various elements, these elements should not be limited by these terms. These terms may be used to distinguish one element from another. For example, a first object or step could be termed a second object or step, and, similarly, a second object or step could be termed a first object or step, without departing from the scope of the disclosure. The first object or step, and the second object or step, are both objects or steps, respectively, but they are not to be considered a same object or step.

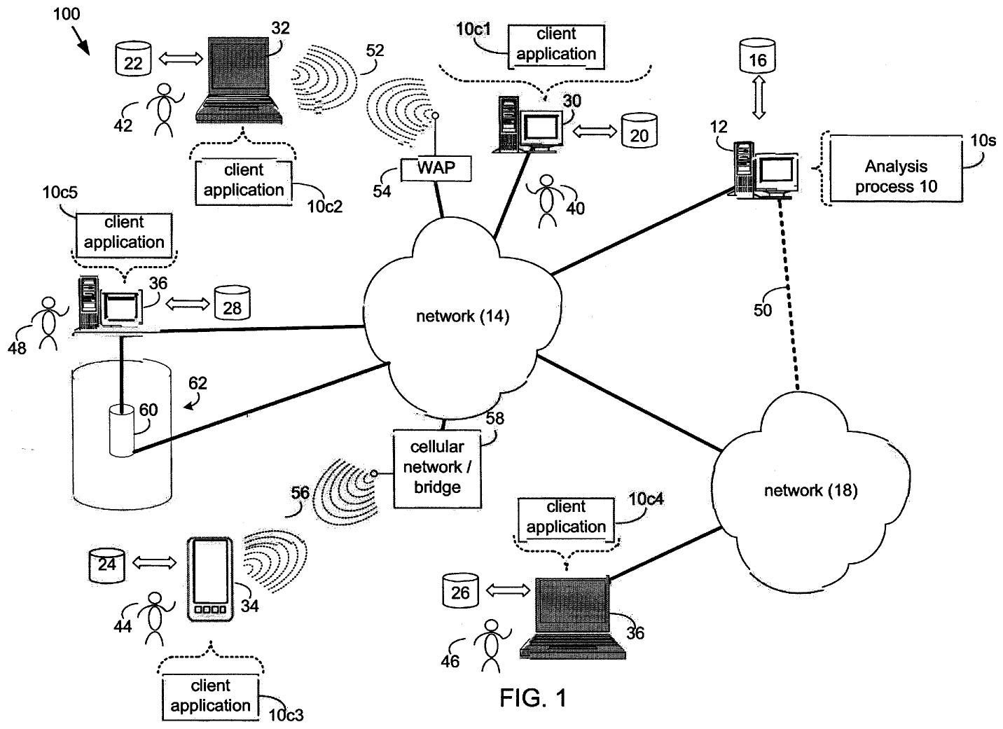

Referring to FIG. 1, there is shown a system diagram that illustrates various arrangements and configurations of devices and networks that may be used in conjunction with reservoir analysis process 10. For the following discussion, it is intended to be understood that reservoir analysis process 10 may be implemented in a variety of ways. For example, reservoir analysis process 10 may be implemented as a server-side process, a client-side process, or a server-side/client-side process.

For example, reservoir analysis process 10 may be implemented as a purely server-side process via reservoir analysis process 10s. Alternatively, reservoir analysis process 10 may be implemented as a purely client-side process via one or more of client-side application 10c1, client-side application 10c2, client-side application 10c3, and client-side application 10c4. Alternatively still, reservoir analysis process 10 may be implemented as a server-side/client-side process via server-side reservoir analysis process 10s in combination with one or more of client-side application 10c1, client-side application 10c2, client-side application 10c3, client-side application 10c4, and client-side application 10c5. In such an example, at least a portion of the functionality of reservoir analysis process 10 may be performed by reservoir analysis process 10s and at least a portion of the functionality of reservoir analysis process 10 may be performed by one or more of client-side application 10c1, 10c2, 10c3, 10c4, and 10c5.

Accordingly, reservoir analysis process 10 as used in this disclosure may include any combination of reservoir analysis process 10s, client-side application 10c1, client-side application 10c2, client-side application 10c3, client-side application 10c4, and client-side application 10c5.

Reservoir analysis process 10s may be a server application and may reside on and may be executed by computing device 12, which may be connected to network 14 (e.g., the Internet or a local area network). Examples of computing device 12 may include, but are not limited to: a personal computer, a server computer, a series of server computers, a mini computer, a mainframe computer, or a dedicated network device.

The instruction sets and subroutines of reservoir analysis process 10s, which may be stored on storage device 16 coupled to computing device 12, may be executed by one or more processors (not shown) and one or more memory architectures (not shown) included within computing device 12. Examples of storage device 16 may include but are not limited to: a hard disk drive; a tape drive; an optical drive; a RAID device; an NAS device, a Storage Area Network, a random access memory (RAM); a read-only memory (ROM); and all forms of flash memory storage devices.

Network 14 may be connected to one or more secondary networks (e.g., network 18), examples of which may include but are not limited to: a local area network; a wide area network; or an intranet, for example.

The instruction sets and subroutines of client-side application 10c1, 10c2, 10c3, 10c4, 10c5 which may be stored on storage devices 20, 22, 24, 26, 28 (respectively) coupled to client electronic devices 30, 32, 34, 36, 38 (respectively), may be executed by one or more processors (not shown) and one or more memory architectures (not shown) incorporated into client electronic devices 30, 32, 34, 36, 38 (respectively). Examples of storage devices 20, 22, 24, 26, 28 may include but are not limited to: hard disk drives; tape drives; optical drives; RAID devices; random access memories (RAM); read-only memories (ROM), and all forms of flash memory storage devices.

Examples of client electronic devices 30, 32, 34, 36, 38 may include, but are not limited to, personal computer 30, 36, laptop computer 32, mobile computing device 34, notebook computer 36, a netbook computer (not shown), a server computer (not shown), a gaming console (not shown), a data-enabled television console (not shown), and a dedicated network device (not shown). Client electronic devices 30, 32, 34, 36, 38 may each execute an operating system.

Users 40, 42, 44, 46, 48 may access reservoir analysis process 10 directly through network 14 or through secondary network 18. Further, reservoir analysis process 10 may be accessed through secondary network 18 via link line 50.

The various client electronic devices (e.g., client electronic devices 28, 30, 32, 34) may be directly or indirectly coupled to network 14 (or network 18). For example, personal computer 28 is shown directly coupled to network 14. Further, laptop computer 30 is shown wirelessly coupled to network 14 via wireless communication channels 52 established between laptop computer 30 and wireless access point (WAP) 54. Similarly, mobile computing device 32 is shown wirelessly coupled to network 14 via wireless communication channel 56 established between mobile computing device 32 and cellular network/bridge 58, which is shown directly coupled to network 14. WAP 48 may be, for example, an IEEE 802.11a, 802.11b, 802.11g, 802.11n, Wi-Fi, and/or Bluetooth device that is capable of establishing wireless communication channel 52 between laptop computer 30 and WAP 54. Additionally, personal computer 34 is shown directly coupled to network 18 via a hardwired network connection.

As generally discussed above, a portion and/or all of the functionality of reservoir analysis process 10 may be provided by one or more of client side applications 10c1-10c5. For example, in some embodiments reservoir analysis process 10 (and/or client-side functionality of reservoir analysis process 10) may be included within and/or interactive with client-side applications 10c1-10c5, which may include client side electronic applications, web browsers, or another application. Various additional/alternative configurations may be equally utilized.

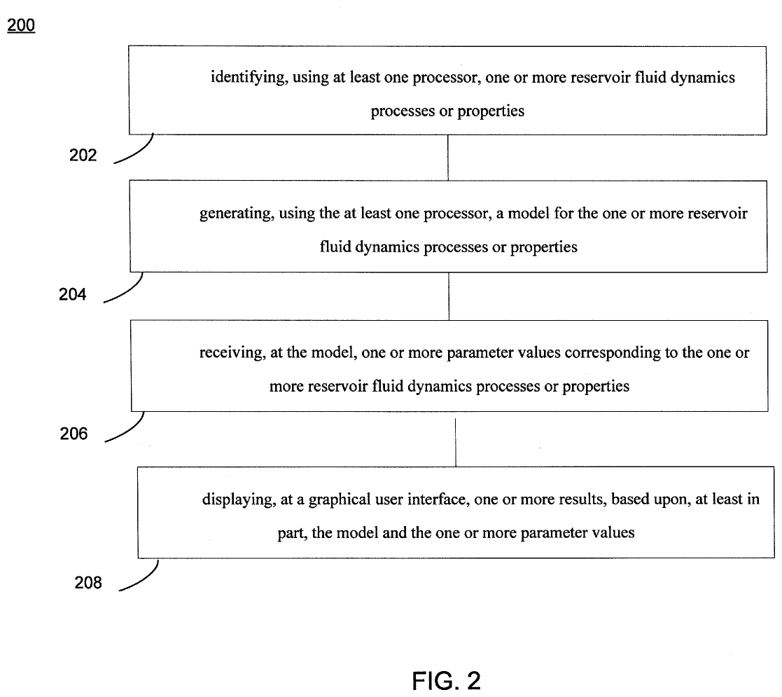

Referring now to FIG. 2, a flowchart 200 showing operations consistent with reservoir analysis process 10 is provided. Reservoir analysis process 10 may provide a system and method for modeling and interpreting an evolution of fluids in an oilfield using artificial intelligence. Embodiments may include identifying (202), using at least one processor, one or more reservoir fluid dynamics processes or properties and generating (204), using the at least one processor, a model for the one or more reservoir fluid dynamics processes or properties. Embodiments may further include receiving (206), at the model, one or more parameter values corresponding to the one or more reservoir fluid dynamics processes or properties. Embodiments may also include displaying (208), at a graphical user interface, one or more results, based upon, at least in part, the model and the one or more parameter values. Numerous other operations are also within the scope of the present disclosure as is discussed in further detail hereinbelow.

As discussed above, the acquisition and interpretation of DFA alongside laboratory measurements of fluid samples acquired downhole (e.g., gas chromatography “GC”) are components of the well appraisal workflow. Many interacting phenomena over significant spans of geologic time (i.e., millions of years) affect the fluid composition observed at the present time. Thus, the interpretation of DFA and lab analyses are generally non-unique and dependent on expert knowledge, experience and creativity. Accordingly, embodiments of the reservoir analysis process 10 described herein, are directed towards an artificial intelligence (AI) framework that addresses a number of elements in this workflow.

Additional information regarding probabilistic modeling and analysis of hydrocarbon-containing reservoirs may be found in US. Pat. Publication Number 20160281497, the contents of which is incorporated by reference in its entirety and is available from the Assignee of the present disclosure. Many of the principles for reservoir fluid dynamics (“RFG”) have been developed, and some of them are summarized in Mullins. See Mullins et al., “The Critical Role of Asphaltene Gradients and Data Integration in Reservoir Fluid Geodynamics Analysis”, paper SPE-187277-MS presented at the SPE Annual Technical Conference and Exhibition held in San Antonio, Tex., USA, 9-11 Oct. 2017.

In some embodiments, reservoir analysis process 10 may be configured to model possible interactions over space and time that yield the measurements seen today. In operation, reservoir analysis process 10, when given the measurements and context, may automatically compute the multiple explanations that satisfactorily explains the observations. In some embodiments, probabilities may be computed for each proposed explanation and using uncertainties with value of information concepts reservoir analysis process 10 may identify the valuable next measurements or analyses that will reduce the uncertainty in competing explanations which are also computed.

In some embodiments, reservoir analysis process 10 may include two broad categories of probabilistic inference determine how to interpret the relevant data. One includes the interpretation of specific measurements (e.g., optical density in DFA to compute probabilistically whether two stations are in equilibrium, degree of biodegradation from GC, etc.). Another inference may include the interpretation of the fluid evolution over time and space. In some embodiments, the measurements and context have been interpreted, and the possible histories probabilistically computed.

In some embodiments, reservoir analysis process 10 may include a causal or probabilistic model that embodies various RFG processes and relates them to the effects on the fluids in the reservoir and measurable properties of the fluids and the reservoir. The causal or probabilistic model may be in the form of a probabilistic Bayesian network, a causal map, or a factor graph, among others. As is discussed in US. Pat. Publication Number 20160281497, these graphs may contain one or more nodes and directed lines (e.g., with arrows on one end) that join a first node or set of nodes to other nodes. In some embodiments, these graphs or maps may contain nodes for variables which may represent measured data, fluid properties, reservoir properties, natural processes that occur, parameters related to these processes, and any additional model parameters. In some embodiments, these properties have some uncertainty or are probabilistic. In a factor graph, there may be additional factor nodes that may represent the operators that transform the nodes leading to them into the nodes they lead to. They describe how the properties from input nodes determine the properties of the output nodes. In other types of graphs, the “factors” are implicit. These operators may represent physical relations given by known equations, or they may reflect more probabilistic relations.

In some embodiments, the models may include one or more plates, where a plate is defined as a repeated instance of a sub-graph and inherits its properties. Plate notation is a method of representing variables that repeat in a graphical model. Instead of drawing each repeated variable individually, a plate or rectangle may be used to group variables into a subgraph that repeat together, and a number is drawn on the plate to represent the number of repetitions of the subgraph in the plate. The assumptions are that the subgraph is duplicated that many times, the variables in the subgraph are indexed by the repetition number, and any links that cross a plate boundary are replicated once for each subgraph repetition. For the RFG processes, plates may be used for different flow units, different locations along an oil column or along a flow unit, and different time units or events. The RFG processes described by such a model may include, but are not limited to, gas charging into oil, biodegradation, tar mat formation, fault block migration, spill-fill, subsidence, uplift, primary charging, water washing, equilibration, diffusion, and advective flow.

In some embodiments, the geological properties impacting these processes may include connectivity, stratigraphy, baffling, faults, sealed faults, shale breaks, anti-clines and tilted sheets. The data may include the type of oil (e.g., gas, condensate, light oil, black oil, heavy oil), optical density, the gas oil ratio (“GOR”), the saturation pressure (Psat), 1D GC, 2D GC, thermal maturity markers, biomarkers for biodegradation, viscosity, CO2, fluid density, and information from seismic, other logs, such as gamma ray, nuclear magnetic resonance (“NMR”) or dielectrics, core extracts, and fluid inclusions. Some additional properties that the model may include are whether or not different aspects of the fluids, such as pressure, asphaltene content, or GOR, are equilibrated.

In some embodiments, reservoir analysis process 10 may generate and populate a causal or probabilistic model representing one or more RFG processes. In cases where enough data is available, some of the model parameters may be trained on the data using a an inference algorithm, some of which may include, but are not limited to, belief propagation, loopy belief propagation, expectation propagation, etc. In some embodiments, this may be set based on expert knowledge of the RFG processes. Once the model has been constructed, then, for a particular well or basin, any known measured data or reservoir properties may be provided. As more information about the well or basin is obtained, the data may be added to the well. At any given point, the model may be used to infer which processes may have occurred in the past or which other properties the fluids or the basin may have. This may be performed using any of the inference algorithms discussed herein.

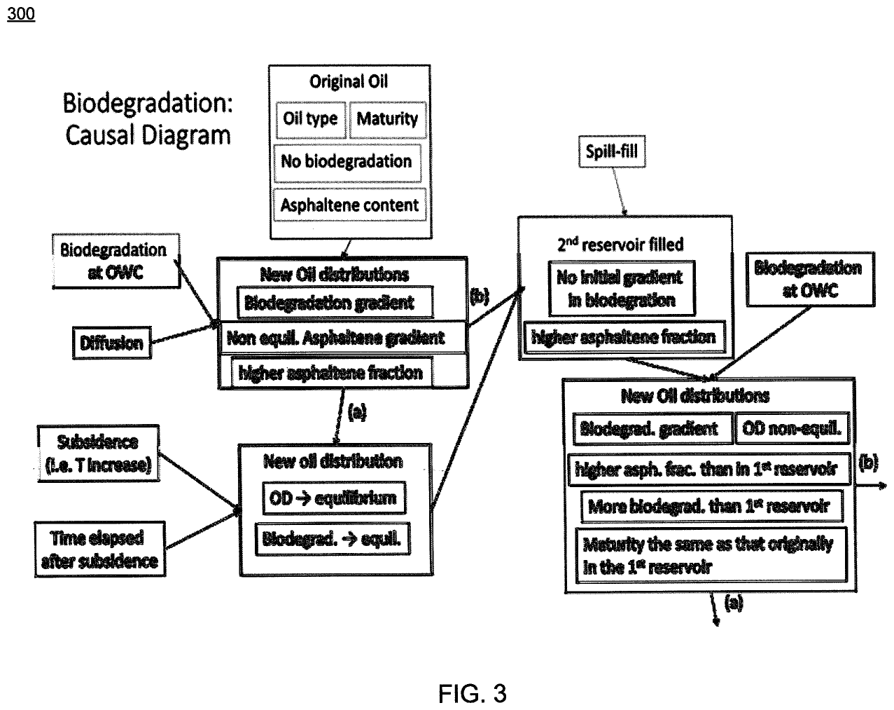

Referring now to FIG. 3, a diagram 300 showing an example of a (higher level) causal diagram for biodegradation, diffusion, subsidence, and spill-fill is provided. This diagram starts with the original non-biodegraded oil, which may be characterized by several properties, including its lack of biodegradation markers, its oil type, asphaltene content, and maturity. The asphaltene content may be determined from downhole optical density measurements or using any other suitable approach. Then, the processes of biodegradation at the oil-water contact and diffusion throughout the oil column may occur. These may lead to the creation of biodegradation markers and increased asphaltene concentration. Thus, the oil has new distributions, most notably new values for the biodegradation markers and optical density, usually with non-equilibrium gradients in these two properties. Other properties, such as the oil maturity, may remain the same. If subsidence then occurs (leading to (a) in FIG. 3), the fluids in the oil column may then equilibrate, leading to equilibrium in the asphaltene fraction (or optical density) and in the biodegradation markers. Additionally and/or alternatively, spill-fill can occur, (leading to (b) in FIG. 3), where the oil from the first reservoir may now fill a second reservoir. This second reservoir may initially start out without an initial gradient in the biodegradation markers, and the asphaltene fraction, after a period of time, may be in equilibrium. Meanwhile, if there are microbes at the oil-water contact in this new reservoir, biodegradation may occur, and this process may repeat in the second reservoir. In addition, the second reservoir could spill over into a third reservoir.

In some embodiments, if biomarkers are measured in a well, the level of biodegradation and the gradient in biodegradation may be entered into this model. If biodegradation markers are observed and no gradient is found in these biomarkers, then the model may infer that biodegradation occurred. In addition, and as shown in FIG. 3, either subsidence occurred, or this reservoir was filled from another reservoir. The model may therefore infer that these are two possible processes that occurred. (A third possibility, not shown in this Figure, is that biodegradation is occurring, but the rate of biodegradation is much slower than the rate of diffusion.).

In this particular example, if asphaltene content and oil maturity are measured, their values may be entered into the model. Usually, asphaltene content may be associated with less mature oil. This would may be taken into account when setting the allowed values in the model for the oil type, asphaltene content and maturity in the original oil properties. As a result, if the measured asphaltene content is relatively high, and the maturity is also relatively high, the model may infer that biodegradation may have occurred. In a more complete model, a gas charge into an oil is another process that may be included. This process may also lead to a high maturity oil with a high asphaltene content. In that case, the model may indicate that there may have been biodegradation or gas charge into the oil, and it may suggest testing for biomarkers (e.g., with 2D GC measurements) to determine which process occurred.

Accordingly, reservoir analysis process 10 may include a model that includes one or more possible interactions over a space and time and includes one or more uncertainties with a value of information. FIG. 3 provides an example depicting the interaction of biodegradation with a spill-fill sequence. In some embodiments, uncertainties may include the uncertainties in the measured downhole optical densities, fluid density, viscosity, gas-oil-ratio, etc.

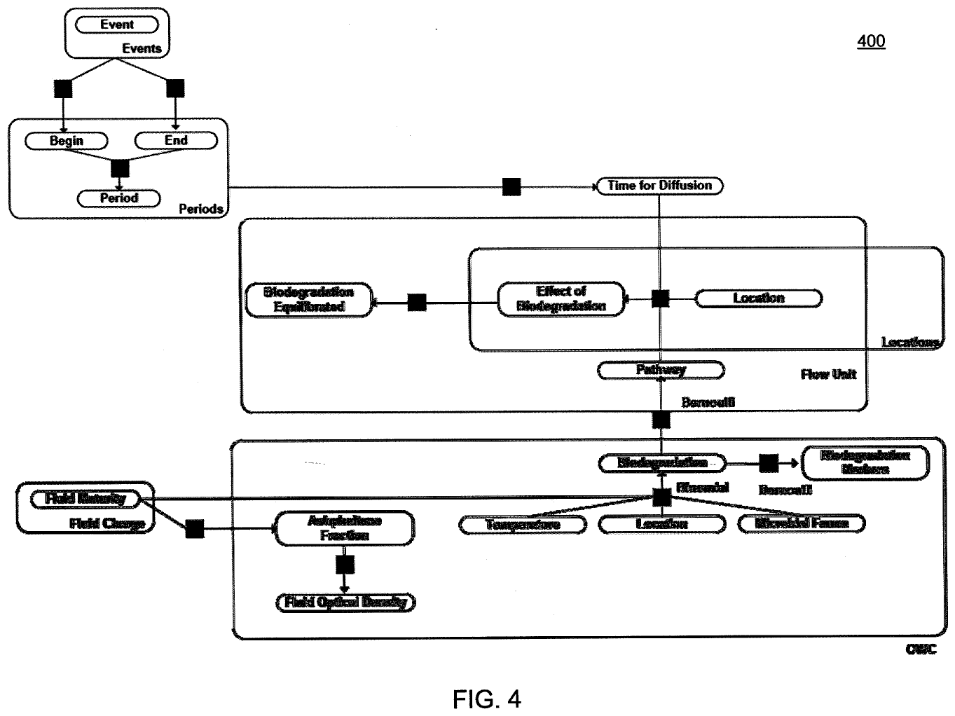

Referring now to FIG. 4, a diagram 400 showing an example of a factor graph is provided. This factor graph focuses on more of the details of biodegradation and its effect on biodegradation markers. In this example, there is a plate for each episode of fluid charging, and each time there is a new charge the fluid may have a different maturity. The next plate may represent the occurrences of biodegradation at oil water contacts. If the temperature is low enough and there are microbial fauna present, then biodegradation may occur, which may produce biodegradation markers. The next plate represents the fluid in a flow unit (or oil column), and this is further divided into its height in the reservoir or horizontal position in the reservoir, which may be represented by the locations plate. The time for diffusion and the pathway for the diffusion may determine the distribution of the biodegradation markers along the flow unit. These may then be checked to see whether or not they form an equilibrium distribution, so that the variable Biodegradation Equilibrated will be true if it is equilibrated and false, otherwise. The events plate may indicate that there is a sequence of events that may take place over time, which lead to periods with different processes. In this case, the start of the event may occur when the reservoir is first charged, and the end of the event could be present time, when the reservoir is measured.

In this particular example, if the variable Biodegradation Markers is equal to true, then the model may infer that biodegradation happened and that the temperature was low enough and microbial fauna were present. Additionally and/or alternatively, if the variable is equal to false, then the model may infer that biodegradation did not happen, and that either the temperature was too high or there was no microbial fauna. Once a process such as biodegradation is identified, it may further be used to optimize the fluid sampling process in a new wellbore, provide constraints on a fluid model in a reservoir or be used to predict the impact on enhanced oil recovery processes.

Accordingly, the examples provided above indicate that a user or computer system may perform the inferences simply by reviewing the causal diagram and/or the factor graph. However, once several different processes are included in greater detail, and a wider range of measured data is included, it may be more difficult for a user to perform the inferences based on these diagrams or their own knowledge. Accordingly, embodiments of reservoir analysis process 10, and the models described herein, when combined with inference algorithms, make it possible, even for a non-expert, to determine which processes are likely to have occurred and what kind of properties the reservoir is likely to have.

In some embodiments, reservoir analysis process 10 may include identifying one or more first RFG processes and properties that are of interest and the measurements that may be available. Reservoir analysis process 10 may allow for the construction of a causal model or factor graph for these processes. The process may allow for input into the causal model of the different ranges and allowed values for each of the parameters, along with the rules for the factor nodes (or combining nodes if not a factor graph). Whenever possible, expert knowledge may be used to fill in these values and rules. If there is enough data, some of these values may be determined by training the system using the data. Next, any known data, known values of properties, and/or processes that are known to have occurred may be entered into the model.

In some embodiments, reservoir analysis process 10 may utilize one or more inference propagation algorithms that may be used to infer which processes may have occurred or to rule out processes and to infer other possible properties of the reservoir that have not been observed. The algorithms may also provide indications of the probabilities for these different processes.

In some embodiments, reservoir analysis process 10 may then combine the model with a program that is configured to display the different probable sequences of events or the probability of a certain RFG process at a graphical user interface.

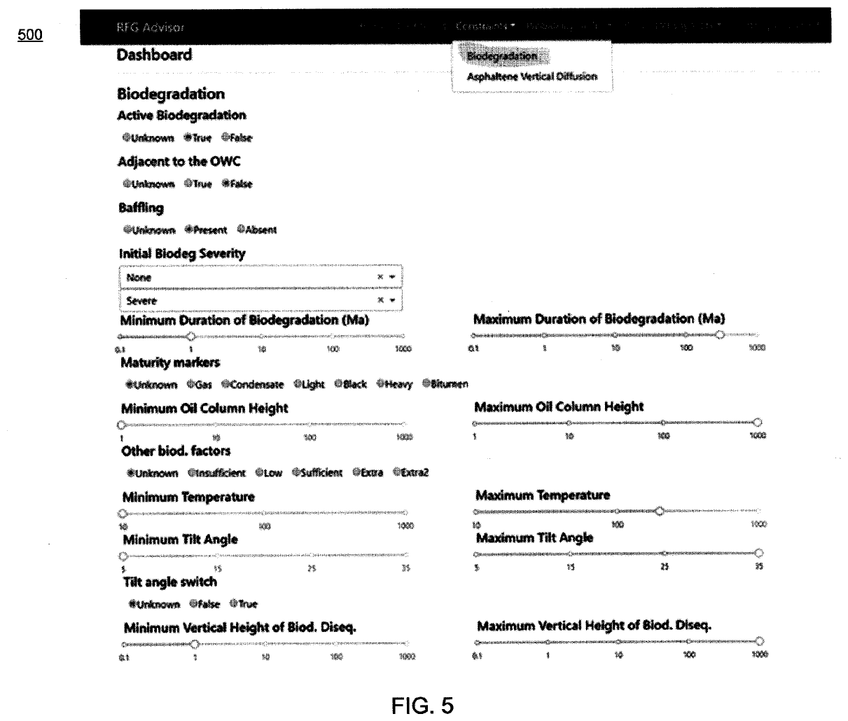

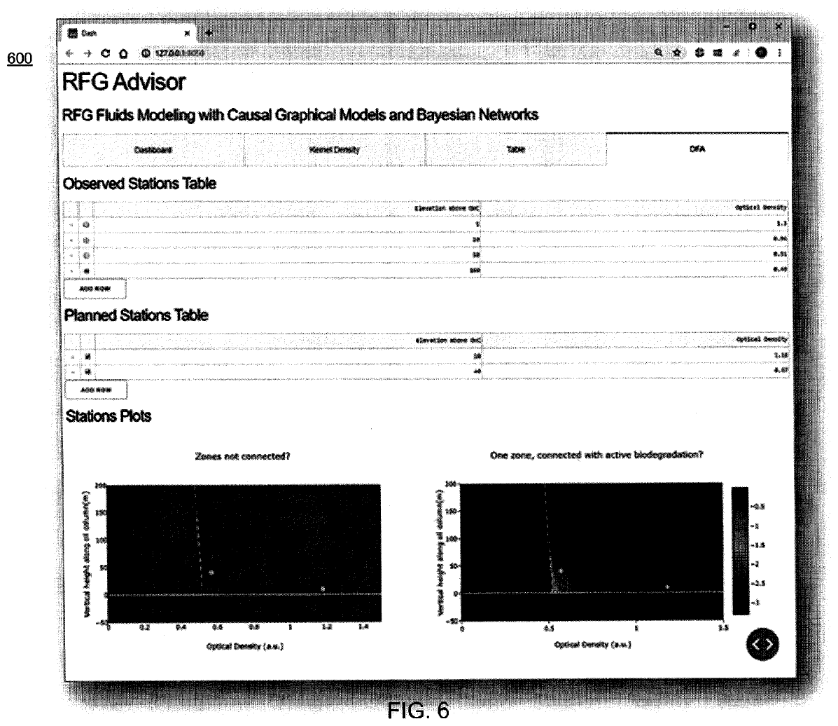

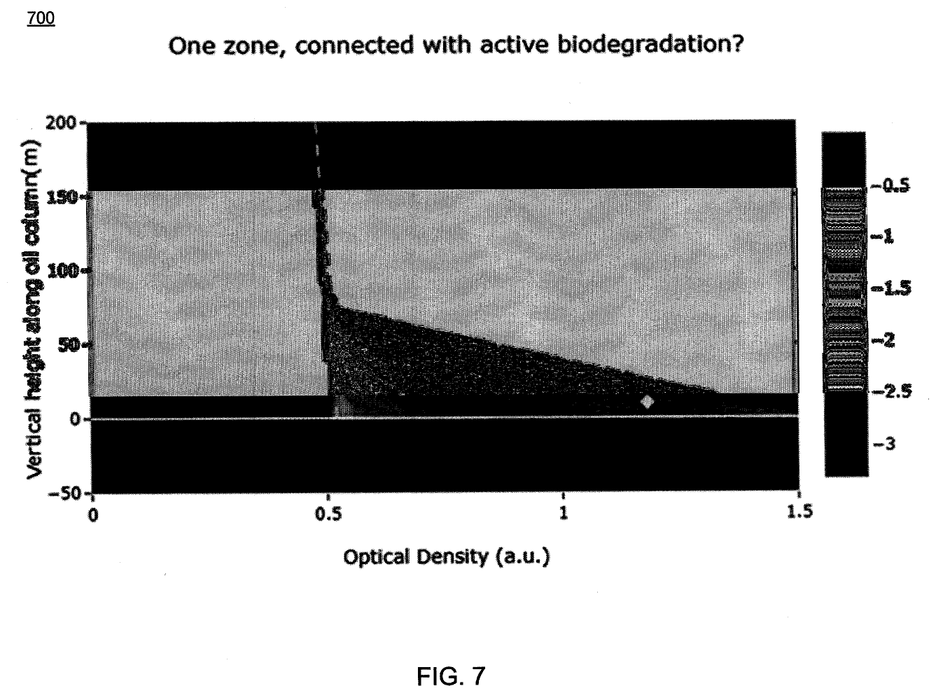

Referring now to FIGS. 5-7, a number of graphical user interfaces consistent with embodiments of reservoir analysis process 10 are provided. As shown in FIG. 5, for a particular RFG process, the constraints requiring user input may be different. GUI 500 may be used to interpret the RFG Causal Probabilistic Model (CPM) directly and build the user interface for controlling the model constraints. FIG. 6 shows a GUI 600 that provides an example of a probabilistic analysis view for interpreting whether observed data is consistent with active biodegradation. FIG. 7 shows a GUI 700 that provides a view of the biodegradation forward model displayed in FIG. 6. This image displays a heatmap of possible optical density values below 80 m above the oil water contact. It illustrates that the four stations between 0 and 80 m are consistent with biodegradation.

In some embodiments, reservoir analysis process 10 may use the model to determine which measurement may distinguish between the different possible scenarios using value of information concepts. As new data is acquired, it may be entered into the model and the inferences can be run. As new processes are identified or new types of data become available, they can be included in the model and the causal model or factor graph can be expanded to include these types of processes or data.

There have been described and illustrated herein several embodiments of methods and systems. While particular embodiments of the invention have been described, it is not intended that the invention be limited thereto, as it is intended that the invention be as broad in scope as the art will allow and that the specification be read likewise. Thus, while particular neural network architectures and workflows have been disclosed, it will be appreciated that other particular architectures and workflows can be used as well. It will therefore be appreciated by those skilled in the art that yet other modifications could be made to the provided invention without deviating from its spirit and scope as claimed.

Some of the methods and processes described above, can be implemented as computer program logic for use with the computer processor. The computer program logic may be embodied in various forms, including a source code form or a computer executable form. Source code may include a series of computer program instructions in a variety of programming languages (e.g., an object code, an assembly language, or a high-level language such as C, C⁺⁺, or JAVA). Such computer instructions can be stored in a non-transitory computer readable medium (e.g., memory) and executed by the computer processor. The computer instructions may be distributed in any form as a removable storage medium with accompanying printed or electronic documentation (e.g., shrink wrapped software), preloaded with a computer system (e.g., on system ROM or fixed disk), or distributed from a server or electronic bulletin board over a communication system (e.g., the Internet or World Wide Web).

Alternatively or additionally, the processor may include discrete electronic components coupled to a printed circuit board, integrated circuitry (e.g., Application Specific Integrated Circuits (ASIC)), and/or programmable logic devices (e.g., a Field Programmable Gate Arrays (FPGA)). Any of the methods and processes described above can be implemented using such logic devices.

In one aspect, any one or any portion or all of the steps or operations of the methods and processes as described above can be performed by a processor. The term “processor” should not be construed to limit the embodiments disclosed herein to any particular device type or system. The processor may include a computer system. The computer system may also include a computer processor (e.g., a microprocessor, microcontroller, digital signal processor, or general purpose computer) for executing any of the methods and processes described above.

The computer system may further include a memory such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device. The memory can be used to store any or all data sets of the methods and processes described above.

The flowcharts and block diagrams in the figures illustrate the architecture, functionality, and operation of possible implementations of systems and methods and according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

Although a few example embodiments have been described in detail above, those skilled in the art will readily appreciate that many modifications are possible in the example embodiments without materially departing from the scope of the present disclosure, described herein. Accordingly, such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112, paragraph 6 for any limitations of any of the claims herein, except for those in which the claim expressly uses the words ‘means for’ together with an associated function.

Having thus described the disclosure of the present application in detail and by reference to embodiments thereof, it will be apparent that modifications and variations are possible without departing from the scope of the disclosure defined in the appended claims.

What is claimed is:

1. A method of modeling and interpreting an evolution of fluids in an oilfield using artificial intelligence comprising:
identifying, using at least one processor, one or more reservoir fluid dynamics processes or properties;
generating, using the at least one processor, a model for the one or more reservoir fluid dynamics processes or properties;
receiving, at the model, one or more parameter values corresponding to the one or more reservoir fluid dynamics processes or properties; and
displaying, at a graphical user interface, one or more results, based upon, at least in part, the model and the one or more parameter values.

2. The method of claim 1, wherein the model is selected from a group consisting of: a probabilistic Bayesian network, a causal map or a factor graph.

3. The method of claim 1, wherein the model includes one or more possible interactions over a space and time and includes one or more uncertainties with a value of information.

4. The method of claim 1, where the model relates the one or more reservoir fluid dynamics processes or properties to one or more effects on the fluids in one or more reservoirs and the one or more reservoir fluid dynamics processes or properties.

5. The method of claim 1, further comprising:
determining one or more ranges of values for the one or more parameter values.

6. The method of claim 1, wherein determining is performed by training, using the at least one processor, the model based upon, at least in part, known values of reservoir fluid dynamics processes or properties.

7. The method of claim 2, further comprising:
determining one or more rules for at least one factor node associated with the factor graph.

8. The method of claim 1, further comprising:
applying one or more inference propagation algorithms to determine whether a particular process has occurred or has not occurred.

9. The method of claim 1, further comprising:
applying one or more inference propagation algorithms to identify a new reservoir fluid dynamics process or property.

10. The method of claim 1, further comprising:
providing the new reservoir fluid dynamics process or property to the model.

11. A system for modeling and interpreting an evolution of fluids in an oilfield using artificial intelligence comprising:
a memory storing one or more reservoir fluid dynamics processes or properties; and
a processor configured to identify one or more reservoir fluid dynamics processes or properties and to generate a model for the one or more reservoir fluid dynamics processes or properties, the processor further configured to receive, at the model, one or more parameter values corresponding to the one or more reservoir fluid dynamics processes or properties; and
a graphical user interface configured to display one or more results, based upon, at least in part, the model and the one or more parameter values.

12. The system of claim 11, wherein the model is selected from a group consisting of: a probabilistic Bayesian network, a causal map or a factor graph.

13. The system of claim 11, wherein the model includes one or more possible interactions over a space and time and includes one or more uncertainties with a value of information.

14. The system of claim 11, where the model relates the one or more reservoir fluid dynamics processes or properties to one or more effects on the fluids in one or more reservoirs and the one or more reservoir fluid dynamics processes or properties.

15. The system of claim 11, wherein the processor is further configured to determine one or more ranges of values for the one or more parameter values.

16. The system of claim 11, wherein determining is performed by training, using the at least one processor, the model based upon, at least in part, known values of reservoir fluid dynamics processes or properties.

17. The system of claim 12, wherein the processor is further configured to determine one or more rules for at least one factor node associated with the factor graph.

18. The system of claim 11, wherein the processor is further configured to apply one or more inference propagation algorithms to determine whether a particular process has occurred or has not occurred.

19. The system of claim 11, wherein the processor is further configured to apply one or more inference propagation algorithms to identify a new reservoir fluid dynamics process or property.

20. The system of claim 11, wherein the processor is further configured to provide the new reservoir fluid dynamics process or property to the model.
